(19) United States
(12) Patent Application Publication
(10) Pub. No.: US 2010/0308754 A1
(43) Pub. Date: Dec. 9, 2010

(54) Hole Transport Polymer for Use in Electronic Devices

(75) Inventors: Neil Gough, Manchester (GB); Ethan Tsai, Boulder, CO (US); William A. Huffman, Longmont, CO (US); Christopher d. Williams, Morrisville, NC (US); Arrelaine A. Dameron, Boulder, CO (US)

Correspondence Address: ARNOLD & KNOBLOCH, L.L.P., 4900 Woodway Dr., Suite 900, HOUSTON, TX, 77056, US

(73) Assignee: HCF PARTNERS, LP, HOUSTON, TX (US)

(21) Appl. No.: 12/741,668

(22) PCT Filed: Nov. 6, 2007
(86) PCT No.: PCT/US07/83764

§ 371 Date: Aug. 24, 2010

(51) Int. Cl. H05B 37/00; H01B 1/12; H01L 51/40; H01L 51/54

(52) U.S. Cl. 315/363; 252/500; 438/99; 257/40; 257/E51.027

(57) ABSTRACT

Organic light emitting diode (OLED) devices are one of the most promising alternatives to liquid crystal displays (LCDs) for flat panel display (FPD) applications. The OLED technique is based on organic semiconductors used either as hole- or electron transporting materials or as an emitter. Working on common problems of performance and life time in OLED preparation, improved charge transport molecules and polymers such as triarylamine- and poly(para-phenylene)-have been developed. Some useful materials include: (1) cyclic triarylamine-derivatives possessing enhanced glass transition temperatures; (2) triarylamine based low molecular mass hole-transport molecules and hole-transport polymers with pendant oxetane groups for processing out of solution and subsequent cross-linking; and (3) fluorenyl-segmented poly(para-phenylene)s with defined electrochemical properties. Provided is a polymer precursor that is useful as a hole transport polymer in OLED and other organic electronic devices.

### BACKGROUND OF THE INVENTION

Organic light-emitting diodes (OLEDs) are currently being widely investigated for many applications such as in the flat-panel display industry, particularly for applications which require low power consumption, high color purity and long lifetime. The basic structure of a multilayer OLED was introduced by Eastman-Kodak in 1987[3] and is based on electroluminescent and semi-conducting organic materials packed between two electrodes as shown in FIG. 1. After charge injection from the electrodes into the organic layer and charge migration within the respective layers (FIG. 2) electrons and deficient electrons (‘holes’) can combine to form an excited singlet state. Light emission of the latter is then as a result of relaxation processes [1, 2].

In order to achieve high electroluminescence efficiency and long life time, the materials have to fulfill several specific requirements [4], which include low injection barriers at the interfaces between electrodes and organic material, balanced electron and hole density/mobility, high quantum efficiency, and the recombination zone should be located away from the metal cathode in order to avoid quenching and high thermal stability. Since no material known to date is able to meet all of these criteria, a modern OLED consists of many components, including a transparent substrate (glass or poly(ethylene terphthalate) (PET), for example); an anode (most commonly indium-tin-oxide: ITO); several organic layers for charge injection, transport and emission [4, 5]; and a metal cathode (Mg—Ag-alloy, Ca, Al, or Ag, for example).

Much of the motivation for studying organic materials for use in OLED devices is related to the potential to tailor their optoelectronic properties and process characteristics by manipulation of the primary chemical structure. For hole-transport or electron blocking layers, triarylamine and pyrazoline structures have been found to be relatively effective [6-8]. For electron-transport or hole blocking purposes a wide variety of electron deficient moieties may be utilized, for example, 1,3,4-oxadiazoles, 1,2,4-triazoles, 1,3-oxazoles, pyridines, and quinoxalines. One specific example is the aluminum derived complex known as Alq3 [9-12]. Highly conjugated compounds such as poly(arylene)s, poly(phenylenevinylene)s, poly(fluorene)s, etc. are useful in the field of polymeric organic semiconductors [12].

Selected examples of small molecules useful in OLED devices include:

### Small Molecule Hole-Transport Materials:

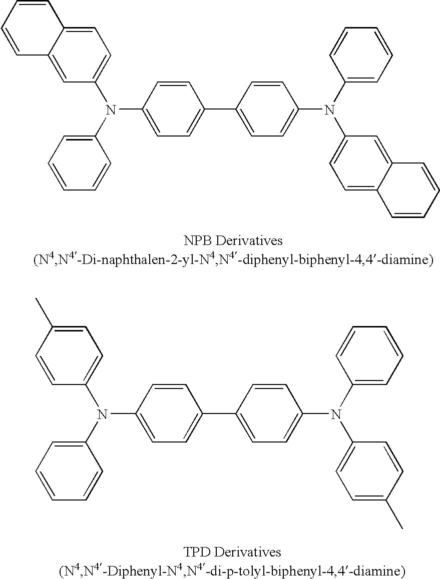

### Small Molecule Electron-Transport Materials:

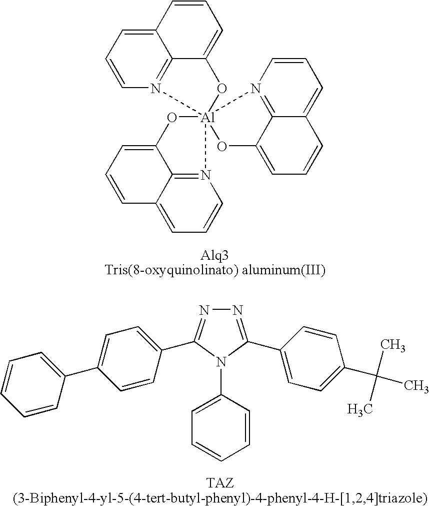

### Polymer Hole-Transport Materials:

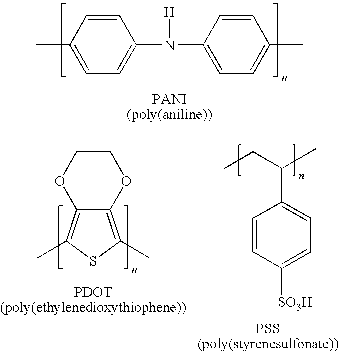

### Polymer Electron-Transport Materials

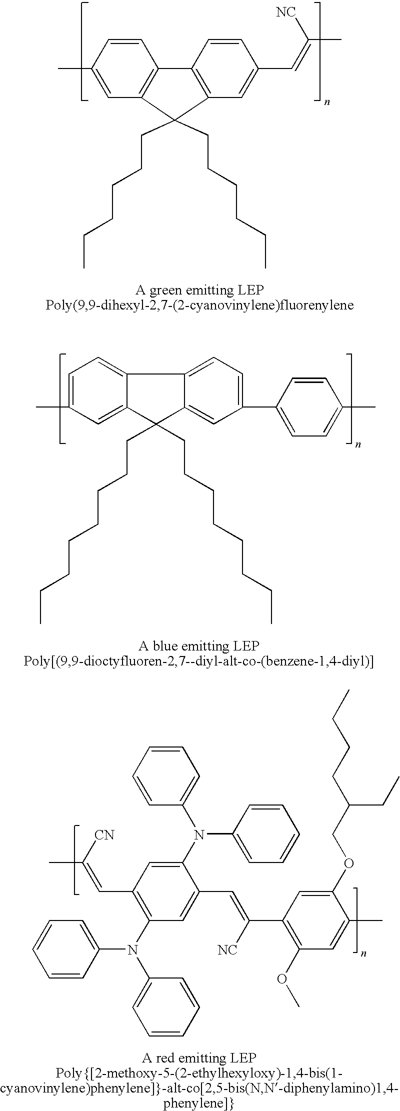

Two basic techniques are commonly employed in the construction of an OLED. In the sublimation process, the organic layers are deposited via vapor deposition and preparation from solution. Vapor deposition provides for a well-defined layer structure possessing excellent purity; however this methodology is only applicable to low molecular mass molecules possessing high thermal stability [13]. Spin coating, dipping or printing methods require soluble materials or precursors [14]. This method is widely used in combination with polymers and dendrimers and provides for a layer structure possessing a high degree of homogeneity and potentially offers a reduction in manufacturing costs when compared to organic vapor deposition methodologies.

In order to achieve a broader degree of commercial acceptance of OLED devices and other electronic devices, it is of great importance to improve the performance of currently existing devices by way of efficiency, lifetime and tenability. It is also important that new non-corrosive materials are developed, which possess improved processability. In particular, there is a demand for materials which can be easily processed from organic solvents and spin coated or ink jet printed onto electrodes to form very smooth thin films.

### SUMMARY OF THE INVENTION

This invention relates generally to organic electronic devices. More specifically, provided is a polymer structure or precursor which can be used in an organic electronic device. In one embodiment, the organic electronic device is an organic electroluminescent device or component thereof, which utilizes organic small molecules or polymers that produce light when transferred into their excited state by an externally applied electric field.

More specifically, provided is a polymer precursor which can be tailored to provide the desired electrical and mechanical properties. The polymer precursor can contain one or more molecules or groups. Generally, provided is a polymer precursor containing a polymerizable group and one or more other optional groups which, when polymerized, is useful as a hole transport polymer in an organic electronic device. Polymerizable groups and other useful groups are known in the art and described here. The polymer precursor or hole transport polymer may contain other compounds which are used to tailor electronic properties of the polymer such as energy levels, or mechanical properties of the polymer, such as aiding in the fabrication of layers using the polymer.

In one embodiment, provided is a polymer precursor for use organic electronic devices comprising:

one or more polymerizable compounds comprising
(1) an acryl group; and
(2) one or more groups selected from the following: a triarylamine group, a phenylamine group, a carbazole group, a thiophene group, and a fluorene group; and
(b) optionally one or more additive compounds comprising
(1) a polymerizable or cross-linkable group; and
(2) one or more groups selected from the following: —CN, R—(CH₂)ₙ, R—R, R-alkene-R, and R—[O—(CH₂)₂—]ₙ, where R is an aromatic group and n is an integer from 1 to 10.

The acryl group and other groups in the polymerizable compound may be connected with any suitable linker, such as those shown herein and other groups known in the art. Some examples are arylene groups, aryl groups, phenylenevinylene, and fluorene groups, for example. The polymerizable compound may also contain additional polymerizable or cross-linkable groups, such as oxetane, trifluorovinyloxy and other groups as described here, or known in the art. Some useful optional additive compounds are described further below, and provide the desired tunability of the electronic and mechanical properties, when combined with one or more polymerizable compounds. Also provided is a polymer comprising the polymer precursor which has been polymerized. Also provided is an organic electronic device containing as a component a polymer which is a polymerized polymer precursor as described herein. In one embodiment, the organic electronic device is an OLED device. In one embodiment, the organic electronic device is a solar cell. In one embodiment, the organic electronic device is a thin film transistor. In different embodiments, there is more than one compound within the polymer to provide the desired properties. In different embodiments, there are two or more compounds within the polymer to provide the desired properties. In an embodiment, there are three or more compounds within the polymer to provide the desired properties. In one embodiment, there are from 1 to 10 different compounds (and all individual values and ranges therein) within the polymer precursor to provide the desired properties. In one embodiment, there are from 1 to 6 different compounds within the polymer precursor to provide the desired properties. Any combination of the compounds and groups described herein may be used in any useful combination.

### DEFINITIONS

As used herein, “polymerizable” compound or group or “polymer” includes a group which can form cross-linkages and oligomers, as well as polymers as conventionally known in the art.

As used herein, an “acryl” group has the structure:

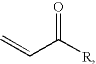

where R can be —O— (where the group is called acrylate); where R can be —NH— (where the group is called acrylamide); or where R can be —S— (where the group is called thio acrylate) and where R can be —C— (where the group is called an α, β-unsaturated ketone).

The use of the word “acryl” is intended to encompass all variations of the R group, unless specifically indicated otherwise. An acryl group may include additional groups on the alkene group, such as a terminal methyl group or other desired group.

As used herein, “layer” does not mean that a perfect layer of material is formed. Rather, as known in the art, certain defects such as pinholes or areas which do not have the material may be present, as long as the defects do not prevent the layer from having the desired characteristics. Also, “layer” may mean that in certain areas, there is more material thickness than in other areas. In specific embodiments, “layer” includes a partial layer up to multiple layers.

As used herein, when two moieties are “attached,” it is to be understood that there is not necessarily a covalent bond between the two moieties. The term “attach” and its grammatical variations refers to a coupling or joining of two or more chemical or physical elements. In some instances, attach can refer to a coupling of two or more atoms based on an attractive interaction, such that these atoms can form a stable structure. Examples of attachment includes chemical bonds such as chemisorptive bonds, covalent bonds, ionic bonds, van der Waals bonds, and hydrogen bonds. Additional examples of attachment include various mechanical, physical, and electrical couplings. Spin-coating, or vapor depositing one substance onto another is an example of “attached.”

The overall fabrication and arrangement of an OLED is known in the art using materials and techniques known in the art. Some examples are given here, however, all suitable known embodiments and components are intended to be included here. The substrate may be rigid or flexible. As is known in the art, a device may contain more than one layer that may be characterized as having the same technical function. For example, there may be more than one different layers in a device that function as an “emissive layer.” All such embodiments are intended to be included here. The structures corresponding to abbreviations used are known in the art. All useful combinations of the various components and layers are intended to be included to the extent as if they were specifically listed.

### BRIEF DESCRIPTION OF THE FIGURES

FIG. 1 shows a typical structure of an OLED device.

FIG. 2 shows an energy level diagram for a typical small molecule OLED device (for example as described in reference 3).

FIG. 3 shows representative ellipsometric data showing thickness versus concentration for one example of films fabricated on PDEOT:OSS films and spun at 2000 rpm for 30 seconds, then 3000 rpm for an additional 30 seconds.

FIG. 4 shows AFM data showing roughness versus film thickness for PEDOT:PSS films on ITO. Roughness data is from 5 μm×5 μm images.

FIG. 5 shows a representative cyclic voltammogram of a polymer 5 film on ITO.

FIG. 6 shows UV-Vis absorption spectra of 0.025 mg/ml polymer 5 in toluene.

FIG. 7 shows a voltage versus luminance plot for polymer 5 utilizing Alq3 as the emitter.

FIG. 8 shows a voltage versus current density plot for polymer 5 utilizing Alq3 as the emitter.

FIG. 9 shows a voltage versus current efficiency plot for polymer 5 utilizing Alq3 as the emitter.

FIG. 10 shows a voltage versus power efficiency plot for polymer 5 utilizing Alq3 as the emitter.

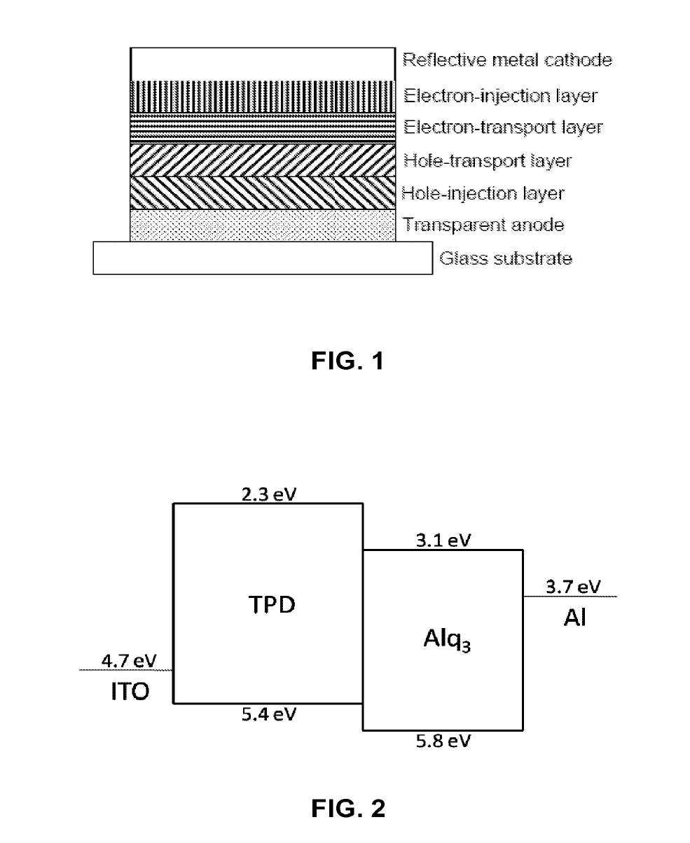

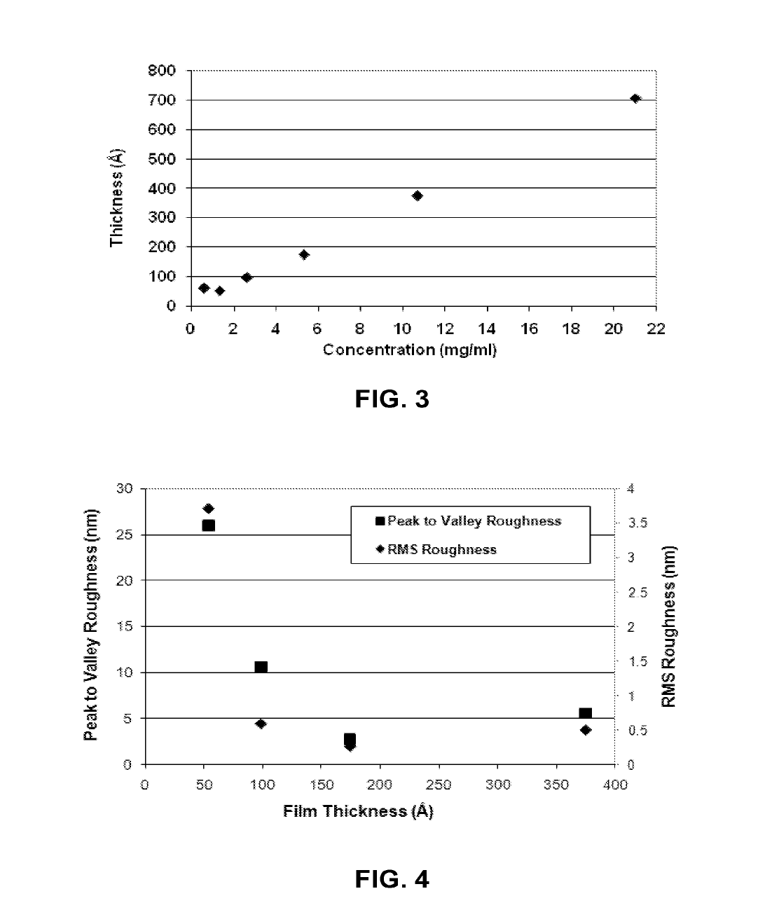

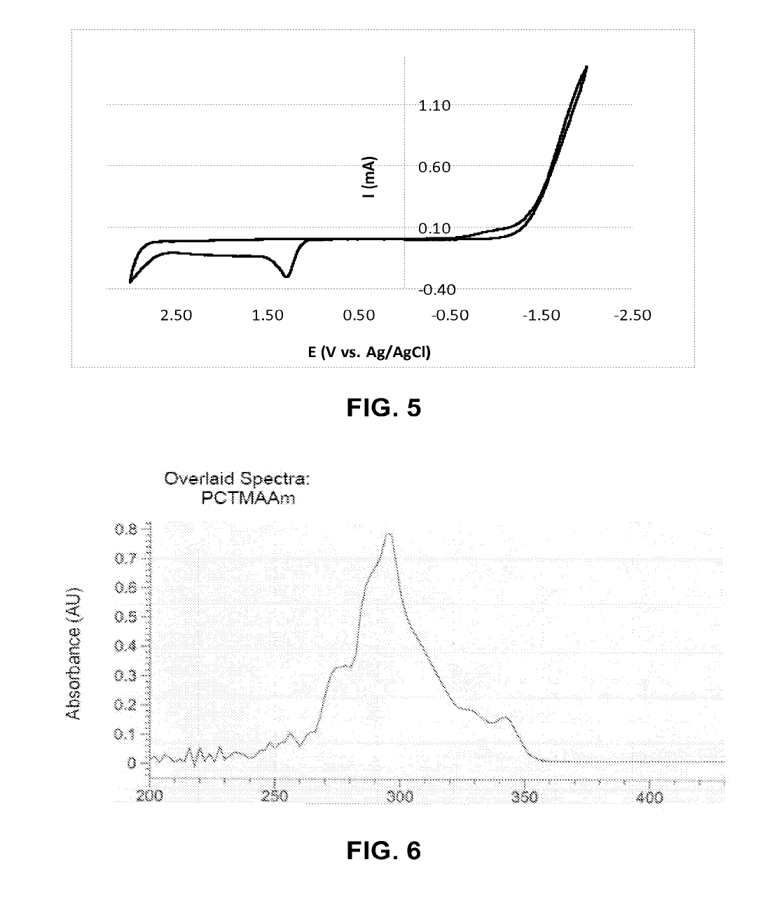

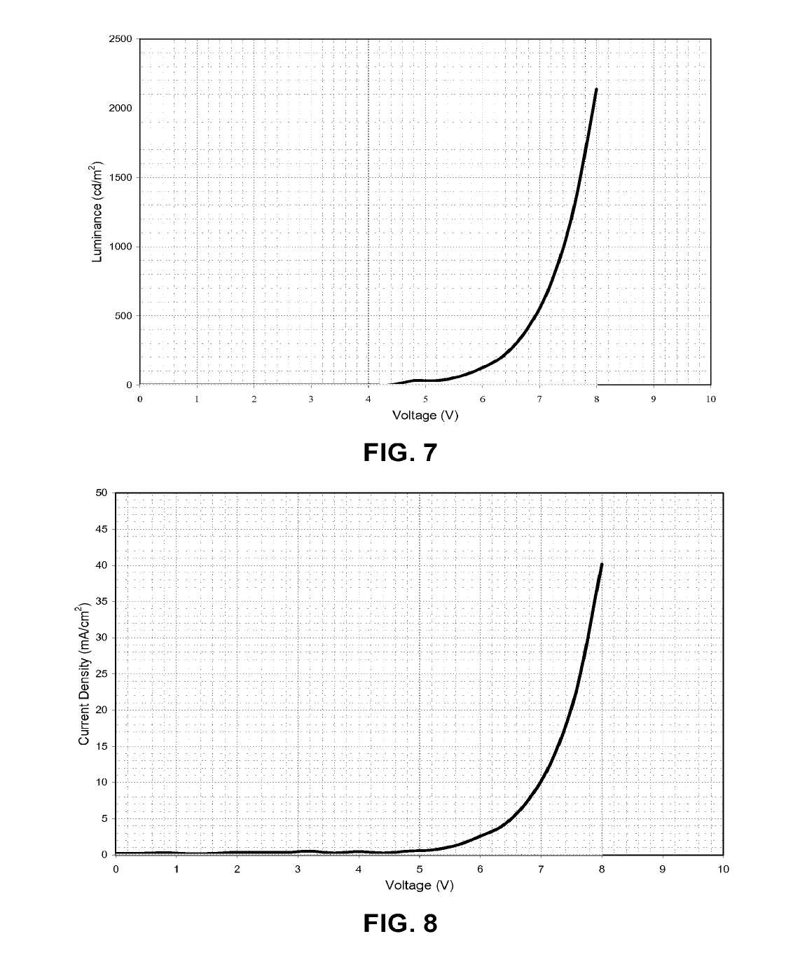

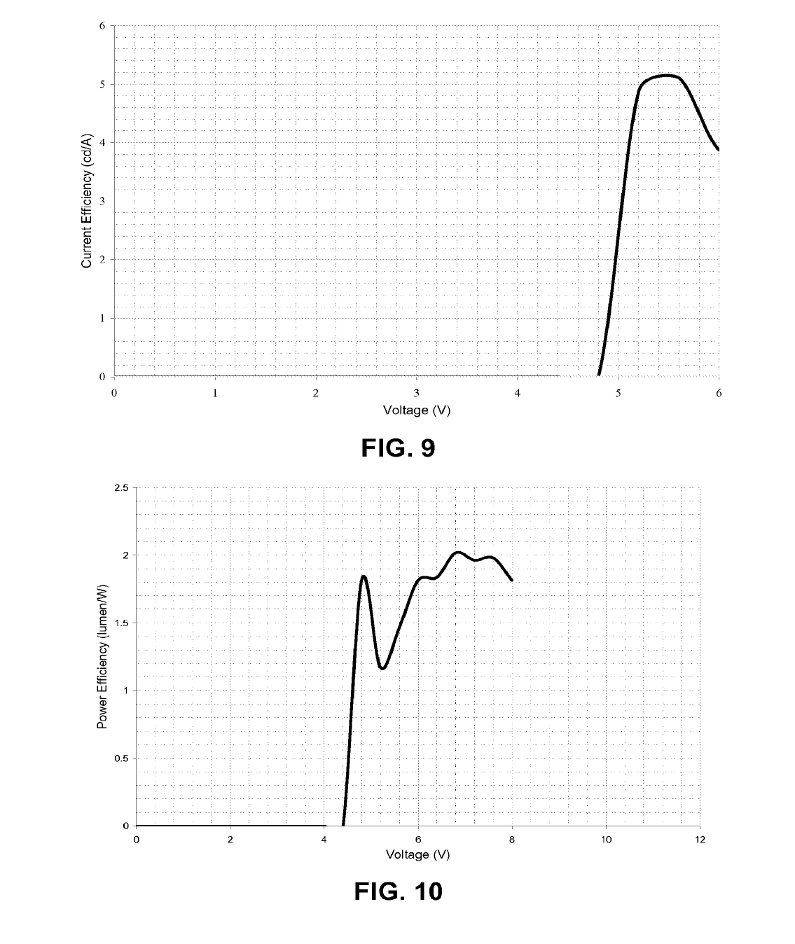

### DETAILED DESCRIPTION OF THE INVENTION

The polymer precursor of the invention comprises one or more compounds which can be polymerized together, or cross-linked together, or any combination. The polymer formed from the polymer precursor may also contain one polymerizable group and other groups which do not form a part of the polymer per se in the resulting polymer, but are constituents in the resulting material after polymerization of the polymerizable group.

As one example, the polymer precursor can contain an acryl group, such as an acrylamide. Acrylamides are useful class of compounds, which may be incorporated in a wide range of applications, providing for a range of new compounds possessing the physical properties of a hole injection layer (HIL) material. Examples of compounds containing an acryl group which are useful in the invention include:

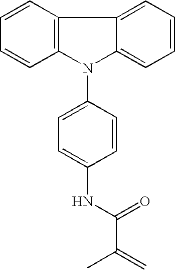

An example of a carbazole type derivative.

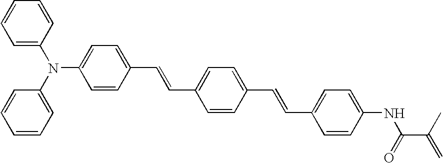

An example of a triphenylamine type derivative.

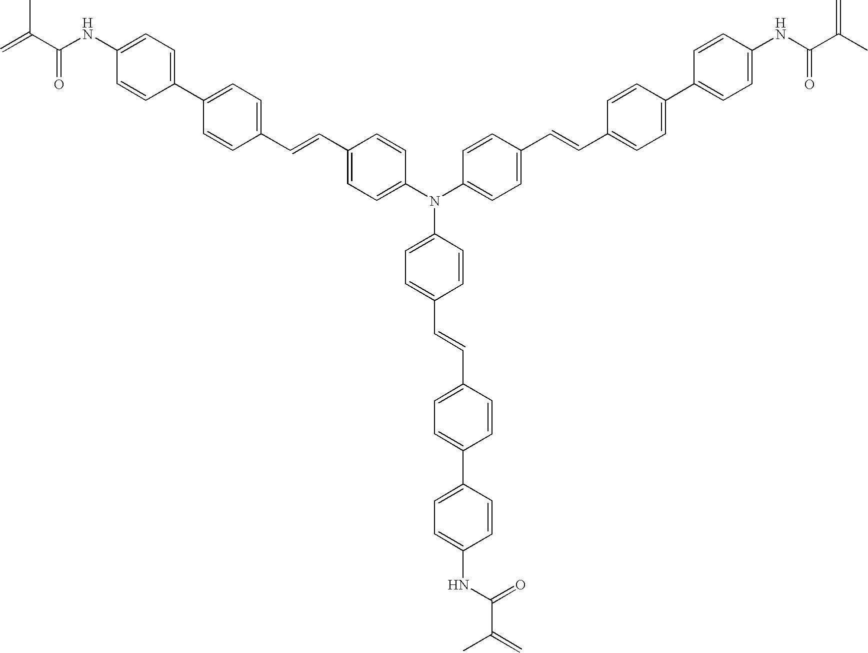

An example of a ‘starburst’ triphenylamine type derivative.

As shown above, the polymer precursor may contain more than one polymerizable group. In one embodiment, the polymer precursor contains one polymerizable group. In one embodiment, the polymer precursor contains more than one polymerizable group. In one embodiment, if the polymer precursor contains more than one polymerizable group, the polymerizable groups are the same. In one embodiment, if the polymer precursor contains more than one polymerizable group, the polymerizable groups are different.

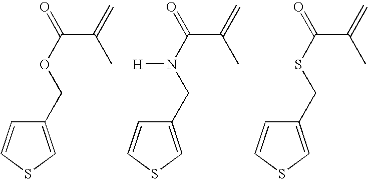

Examples of thiophene based compounds.

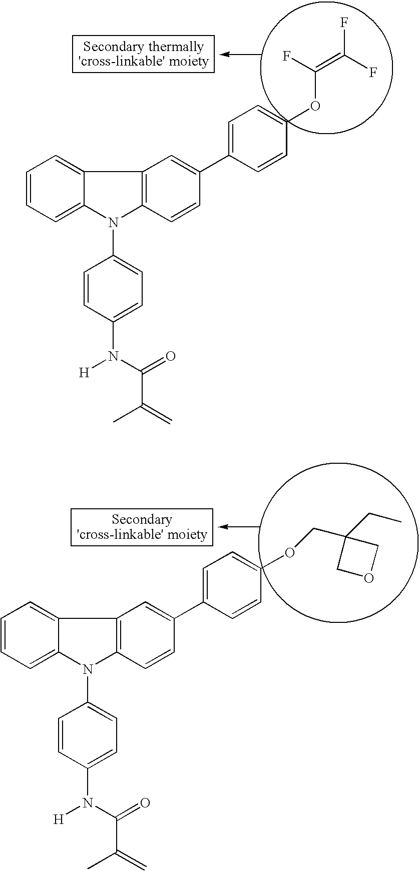

Examples of compounds possessing a secondary cross-linkable moiety.

As shown above, there may be additional polymerizable or cross-linkable groups present in the polymerizable compound.

Each of the above examples are capable of being polymerized or cross-linked in a controlled manner, providing materials that are soluble in a wide range of organic solvents, such as chloroform and toluene and provide effective hole-transport layers when incorporated in an OLED device.

The composition of the polymer may also be controlled in a highly controlled manner providing polymers possessing very specific electronic and mechanical properties. This embodiment may be achieved by carrying out a polymerization with more than one type of compound possessing either/or an acrylate or acrylamide moieties, for example. In addition, additional compounds may be used in the polymer. By way of example, the electronic properties of the resulting material can be adjusted by including one or more of the following compounds in varying percentages:

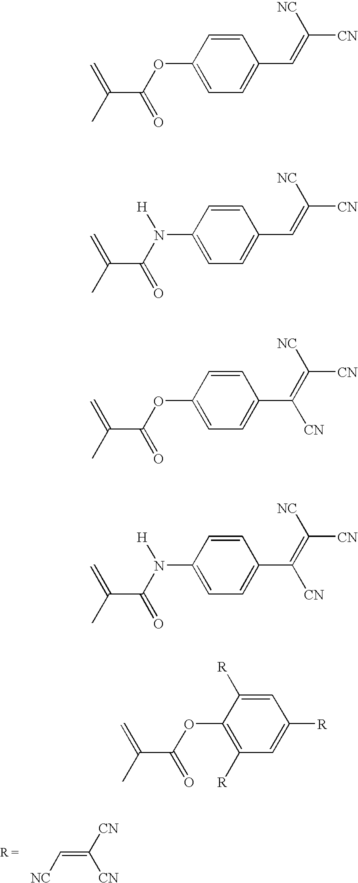

Examples of possible additives that could be used to adjust the electronic properties of the resulting polymer.

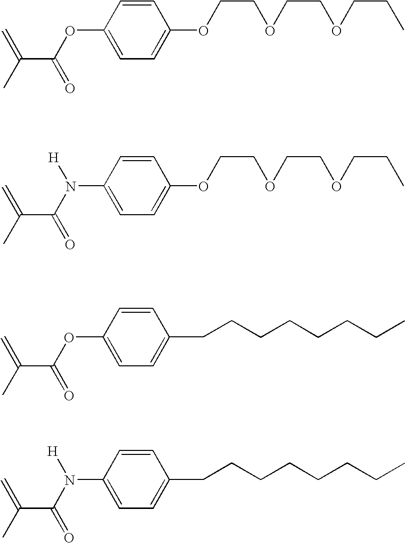

Examples of possible additives that could be used to adjust the mechanical and processing properties of the resulting polymer.

The amount of the additive compounds may be any suitable amount which provides the desired effect. These amounts are known by one of ordinary skill in the art without undue experimentation. Some exemplary amounts of the additive compounds are up to 1% by weight of the total composition, up to 5% by weight of the total composition, up to 10% by weight of the total composition, up to 15% by weight of the total composition, up to 20% by weight of the total composition, up to 25% by weight of the total composition, and all individual values and ranges therein.

### EXAMPLES

The following examples are provided to illustrate some non-limiting embodiments of the invention. In the Schemes, exemplary reactions and reagents are shown. Methods of synthesis of various compounds is known in the art.

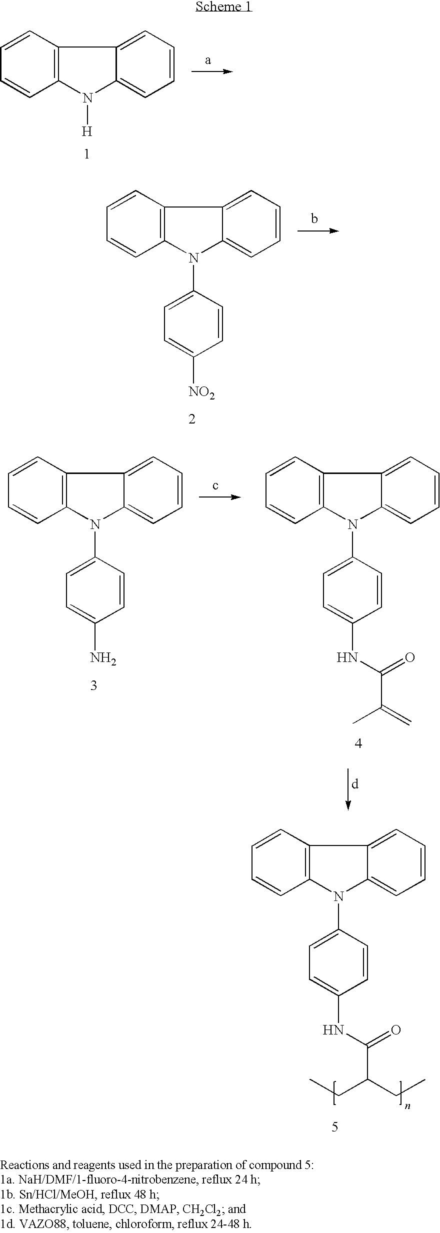

### Synthesis of 9-(4-nitrophenyl)-9H-carbazole (2)

Sodium hydride (1.85 g, 0.077 mol) was added to a solution of carbazole (11.70 g, 0.070 mol) in N,N-dimethylformamide (DMF) (100.0 ml) and the reaction mixture stirred at room temperature under an atmosphere of dry nitrogen for ten minutes. 1-Fluoro-4-nitrobenzene (7.53 ml, 0.071 mol) was added in portions and the reaction mixture heated under reflux for 16 h, cooled to room temperature and poured onto water (300 ml). The precipitate was collected by filtration and re-crystallized repeatedly from acetonitrile. ¹H NMR (500 MHz, CDCl₃) δ/ppm: 8.49-8.51 (dt, 2H, aromatic), 8.15-8.17 (dt, 2H, aromatic), 7.81-7.83 (dt, 2H, aromatic), 7.45-7.52 (m, 4H, aromatic), 7.35-7.38 (td, 2H, aromatic).

### Synthesis of 4-(9H-carbazol-9-yl)aniline (3)

A suspension of compound 2 (9.20 g, 31.9 mmol), tin granules (11.4 g, 95.7 mmol), hydrochloric acid (15.1 ml, 153.0 mmol, 37%) in methanol (200 ml) was heated under reflux for 16 h. The reaction mixture was cooled to room temperature, filtered, neutralized with excess sodium bicarbonate solution (aqueous) and the organic layer extracted into chloroform (3×150 ml) and the combined extracts dried (MgSO₄), filtered and the solvent removed in vacuo providing a viscous oil. The crude product was purified by columned chromatography [silica gel, eluted with 2:1 hexanes:ethyl acetate, containing 1% methanol] providing a colorless oil. ¹H NMR (500 MHz, CDCl₃) δ/ppm: 8.19 (dt, 2H, aromatic), 7.45 (m, 2H, aromatic), 7.38 (dt, 2H, aromatic), 7.30-7.34 (m, 4H, aromatic), 6.87 (dt, 2H, aromatic), 3.84 (s, 2H, NH₂).

### Synthesis of N-(4-(9H-carbazol-9-yl)phenyl)methacrylamide (4)

Methacrylic acid (0.608 ml, 7.16 mmol) was added to a solution of N,N-dicyclohexylcarbodiimide (DCC) (1.48 g, 7.16 mmol) in dichloromethane (DCM) (30 ml) and the reaction mixture stirred for 30 seconds before compound 3 (1.68 g, 6.51 mmol) was added. N,N-dimethylamino pyridine (DMAP) (0.088 g, 0.716 mmol) was added and the reaction mixture stirred at room temperature for 16 h. The reaction was filtered, the solvent removed in vacuo and the residues purified by column chromatography [silica gel eluted with dichloromethane] to provide a white solid, which was re-crystallized from toluene and hexane providing colorless crystals. ¹H NMR (400 MHz, CDCl₃) δ/ppm: 8.14-8.16 (dt, 2H, aromatic), 7.80-7.83 (dt, 2H, aromatic), 7.63 (s, 1H, NH), 7.53-7.56 (dt, 2H, aromatic), 7.37-7.42 (m, 4H, aromatic), 7.27-7.31 (m, 2H, aromatic), 5.88 (s, 1H, CH), 5.54 (d, 1H, CH), 2.13 (dd, 3H, CH₃).

### Synthesis of poly-N-(4-(9H-carbazol-9-yl)phenyl)methacrylamide (5)

A solution of compound 4 (46.7 mg, 1.43 mmol) and 1,1′-azobis(cyclohexanecarbonitrile) (DuPont as VAZO 88) (17.5 mg, 0.072 mmol) in toluene (3.0 ml) and the reaction mixture heated under reflux for 48 h under an atmosphere of dry nitrogen. The resulting polymer was precipitated in methanol and centrifuged out of suspension. The supernate was discarded and the polymer re-dispersed in fresh methanol before being centrifuged out of suspension once again. The polymer was then dried under vacuum and used without further purification.

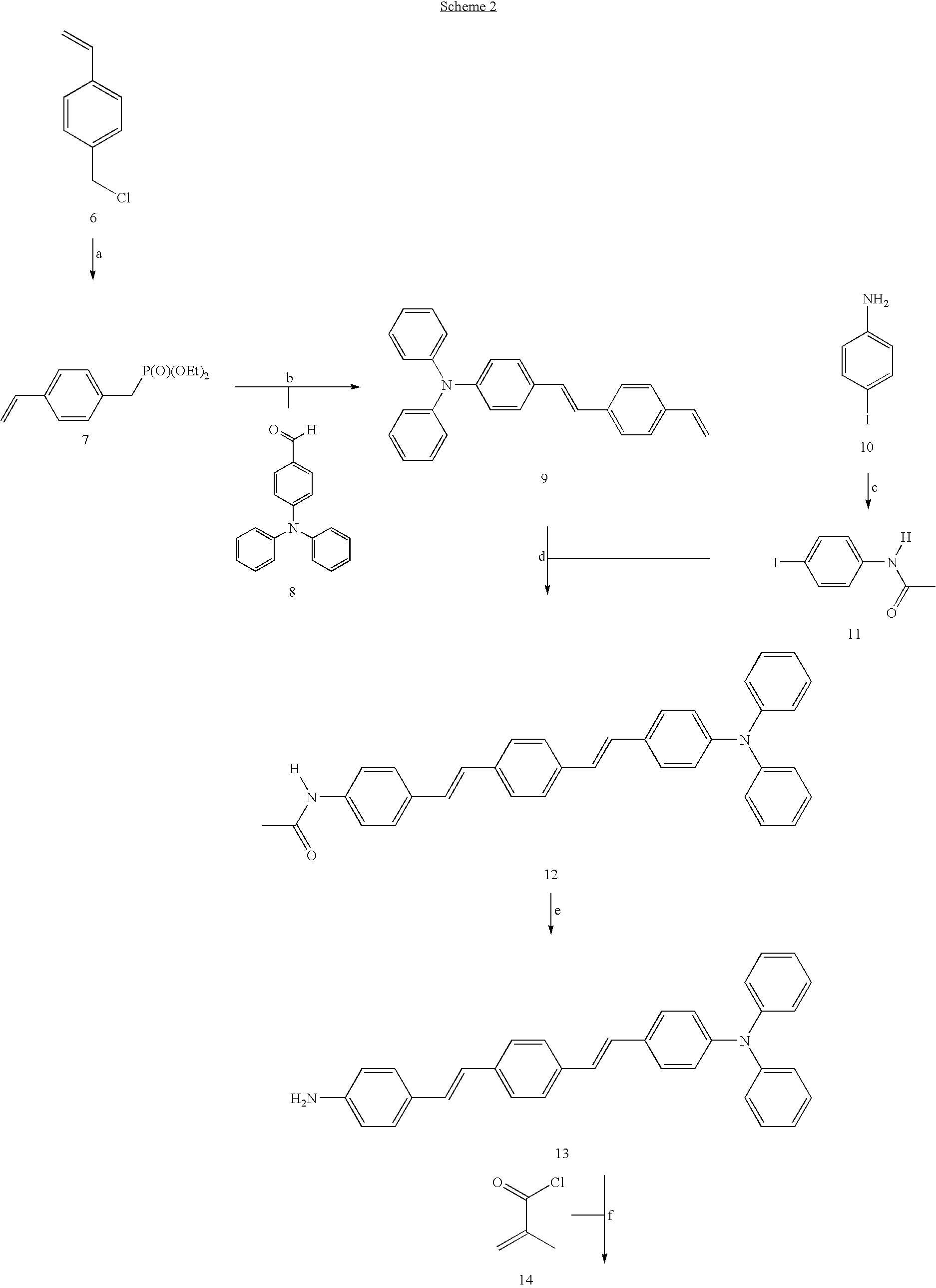

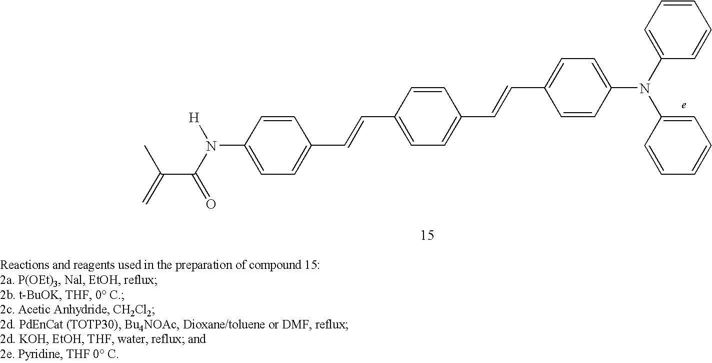

### 4-vinyl benzyl diethylphosphonate ester (7)

A suspension of 4-vinylbenzyl chloride (20.00 g, 130.00 mmol), triethyl phosphite (16.60 g, 100.00 mmol) and sodium iodide (1.50 g, 10.00 mmol) in ethanol (EtOH) (150 ml) was heated under reflux under an atmosphere of dry nitrogen for 24 h. The reaction mixture was cooled to room temperature, concentrated in vacuo and the residues dissolved in ethyl acetate (EtOAc) (150 ml), washed with saturated sodium carbonate solution in water (100 ml) and the organic phase extracted into ethyl acetate (100 ml×4). The combined extracts were dried (MgSO₄), filtered, the solvent removed in vacuo and the residues purified by column chromatography [silica gel eluted with a graduated eluent from 100% hexane to 100% ethyl acetate] providing a colorless oil (22.4 g, 88.0 mmol, yield 88%).

### Diphenyl-{4-[2-(4-vinyl-phenyl)-vinyl]-phenyl}-amine (9)

A solution of compound 7 (14.37 g, 56.53 mmol) and 4-diphenylamino-benzaldehyde (15.03 g, 56.53 mmol) in tetrahydrofuran (THF) was added dropwise to a stirred, cooled (0° C.) solution of potassium t-butoxide (12.34 g, 110 mmol) under an atmosphere of dry nitrogen. The reaction mixture was warmed to room temperature and stirred for 16 h, the solvent removed in vacuo and the residues dissolved in water (100 ml) and the organic phase extracted in to dichloromethane (CH₂Cl₂, 100 ml×2). The combined organic extracts were dried (MgSO₄), filtered, evaporated and washed with hexane providing a white solid (15.0 g, yield 71%).

### N-(4-Iodo-phenyl)-acetamide (11)

A solution of acetic anhydride (2.04 g, 20.0 mmol) in DCM (10.0 ml) was added dropwise to solution of 4-iodoaniline (2.20 g, 10.0 mmol) in DCM (20.0 ml) under an atmosphere of dry nitrogen. On complete addition, the reaction mixture was heated to reflux for 12 h, cooled to 0° C. and the product collected under filtration. Yield 2.0 g, 77%.

### N-[4-(2-{4-[2-(4-Diphenylamino-phenyl)-vinyl]-phenyl}-vinyl)-phenyl]-acetamide (12)

A suspension of compound 9 (0.50 g, 1.34 mmol), compound 11 (0.45 g, 1.34 mmol), PdEnCat (0.17 g, 0.067 mmol, TOTP30) and tetrabutylammonium acetate (1.00 g, 3.34 mmol) in toluene (40 ml) and dioxane (40 ml) was heated under reflux under an atmosphere of dry nitrogen for 72 h. The reaction mixture was poured on to water (300 ml) and the resulting precipitate collected by filtration. The solid obtained was dissolved in THF, dried (MgSO₄), the solvent removed in vacuo and the crude product purified by column chromatography [silica gel eluted with a graduated eluent from 50% hexane: CH₂Cl₂, to CH₂Cl₂ to CH₂Cl₂:THF, 9:1] providing a brown solid that was re-crystallized from EtOAc to providing brown crystals (0.52 g, 76%).

### 4-(2-{4-[2-(4-Diphenylamino-phenyl)-vinyl]-phenyl}-vinyl)-aniline (13)

A solution of compound 12 (0.50 g, 1.00 mmol), potassium hydroxide (0.30 g, 5.30 mmol) in THF (20 ml), ethanol (20 ml) and water (1.0 ml) was heated under reflux for 24 h. The reaction mixture was cooled to room temperature and the precipitate collected under filtration, washed with water and recrystallized from EtOAc providing brown crystals. Yield 0.46 g, 100%. ¹H NMR (500 MHz, CDCl₃) δ/ppm: 7.42-7.45 (m, 5H, aromatic), 7.33-7.04 (m, 4H, aromatic), 7.22-7.30 (m, 6H, aromatic), 7.0-7.17 (m, 11H, aromatic), 6.50 (2, 2H, N—H).

### N-[4-(2-{4-[2-(4-Diphenylamino-phenyl)-vinyl]-phenyl}-vinyl)-phenyl]-2-methyl-acrylamide (14)

Methacrylic acid (0.0215 mL, 0.2500 mmol) was added to a solution of DCC (0.0516 g, 0.2500 mmol), in DCM (10 cm³), and allowed to react for thirty seconds. After 30 seconds, the solution was rapidly charged with compound 13 (0.1058 g, 0.2300 mmol) and DMAP) (0.0031 g, 0.025 mmol) and the suspension stirred for 16 h under an atmosphere of dry nitrogen. The suspension was filtered and the solids rinsed with DCM and residues purified by column chromatography [silica gel, eluted with 1% methanol in hexanes] providing a color solid. ¹H NMR (400 MHz, CDCl₃) δ/ppm: 7.57-7.60 (dt, 2H, aromatic), 7.48-7.54 (m, 7H, aromatic), 7.38-7.42 (dt, 2H, aromatic), 7.24-7.30 (m, 4H, aromatic), 7.10-7.14 (dt, 4H, aromatic), 7.00-7.08 (m, 7H, aromatic), 5.81 (s, 1H, vinyl C—H), 5.49 (d, 1H, vinyl C—H), 5.30 (s, 1H, N—H), 2.08 (s, 3H, allylic CH₃).

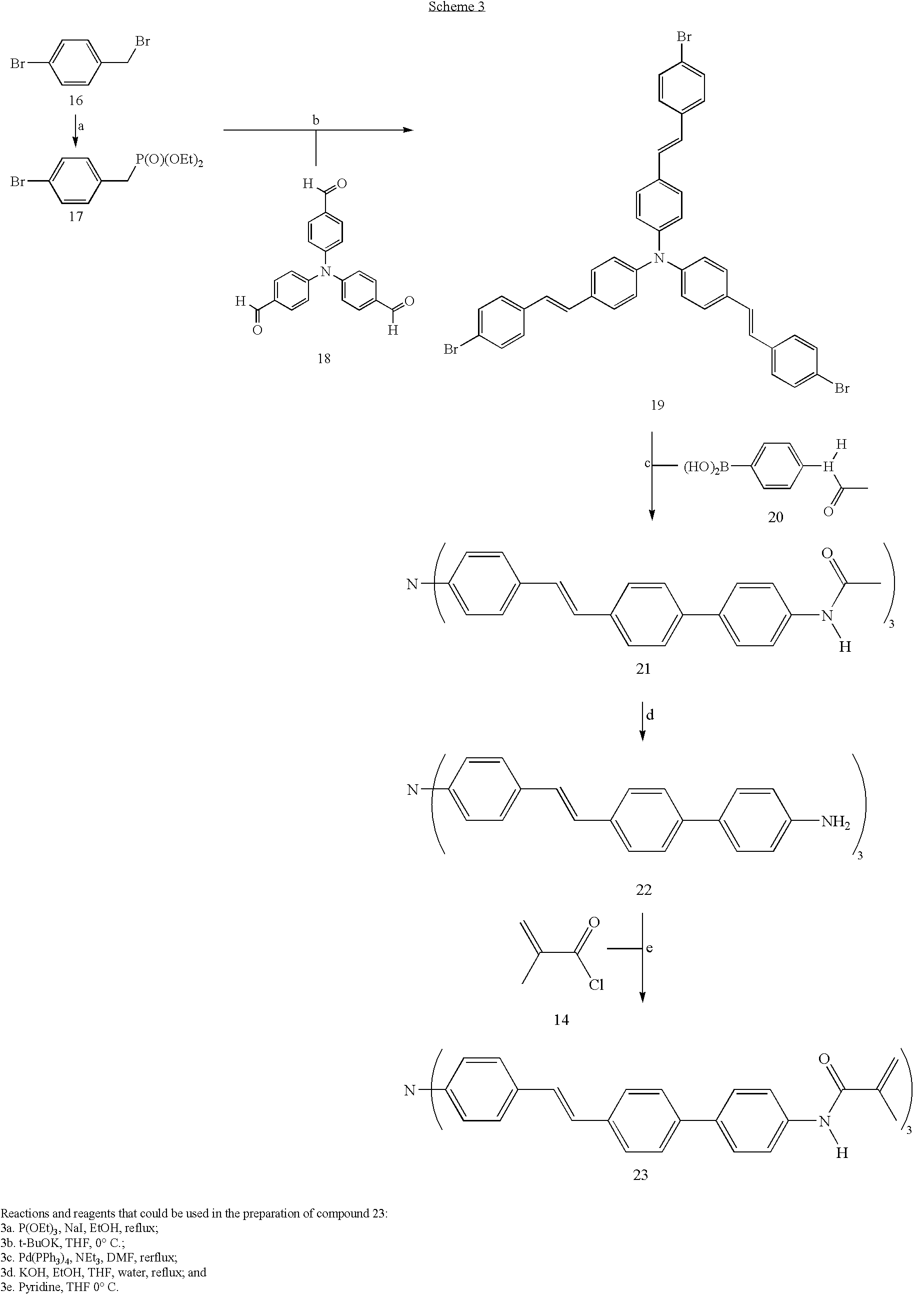

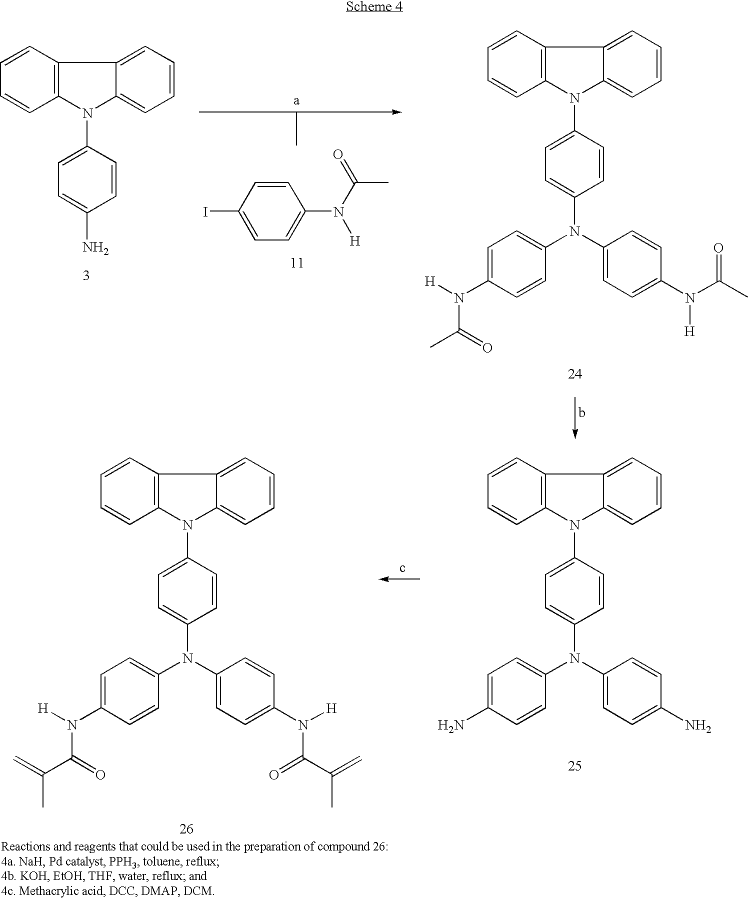

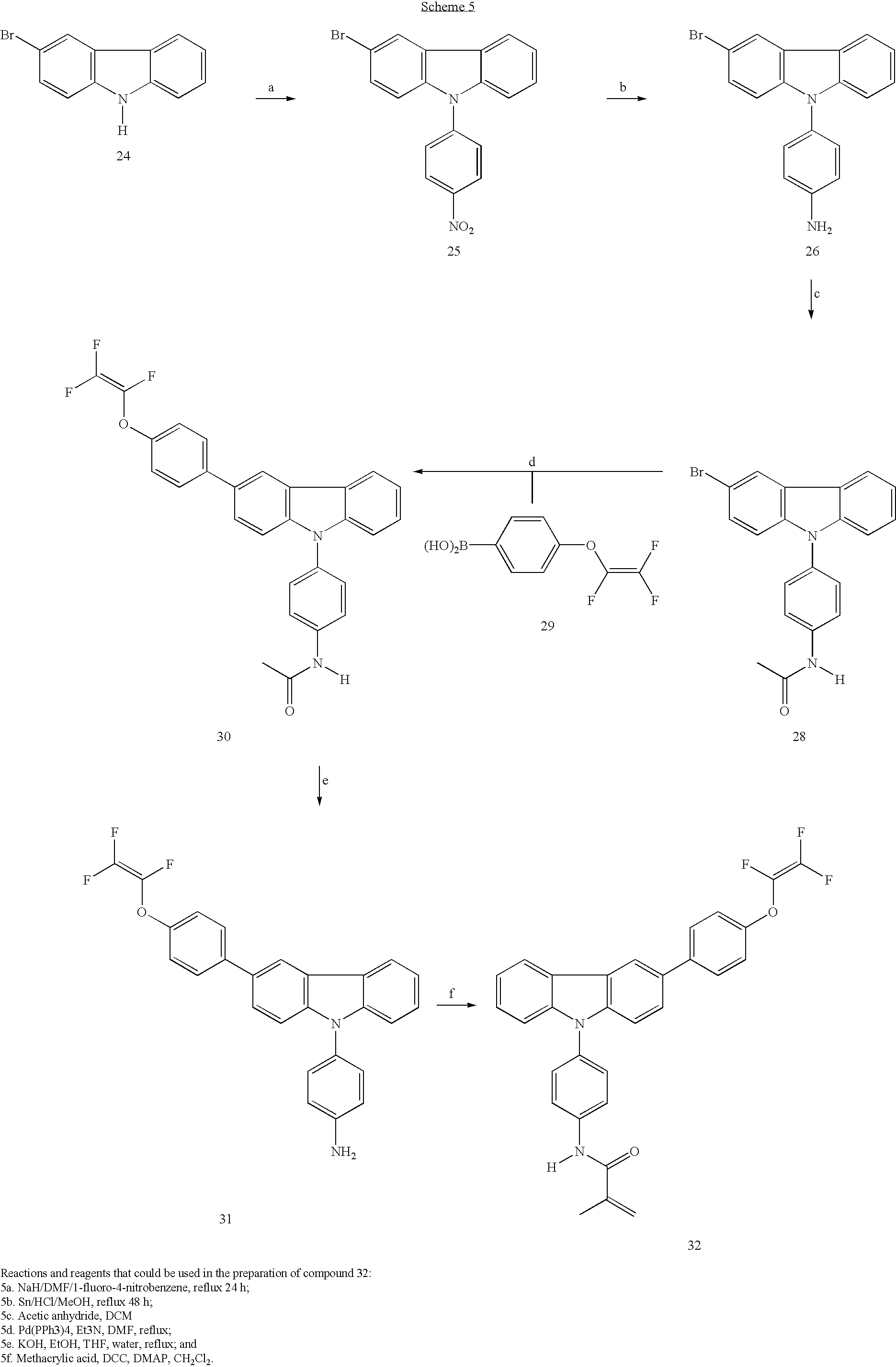

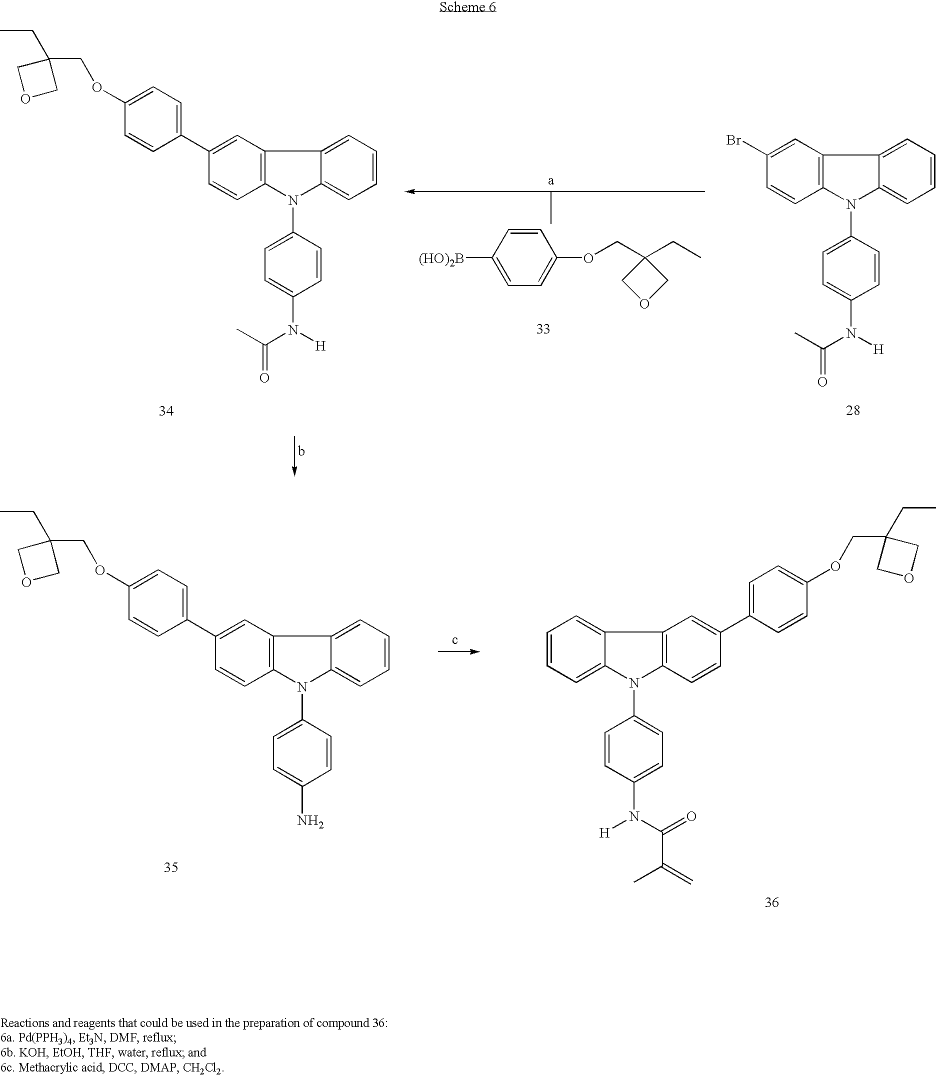

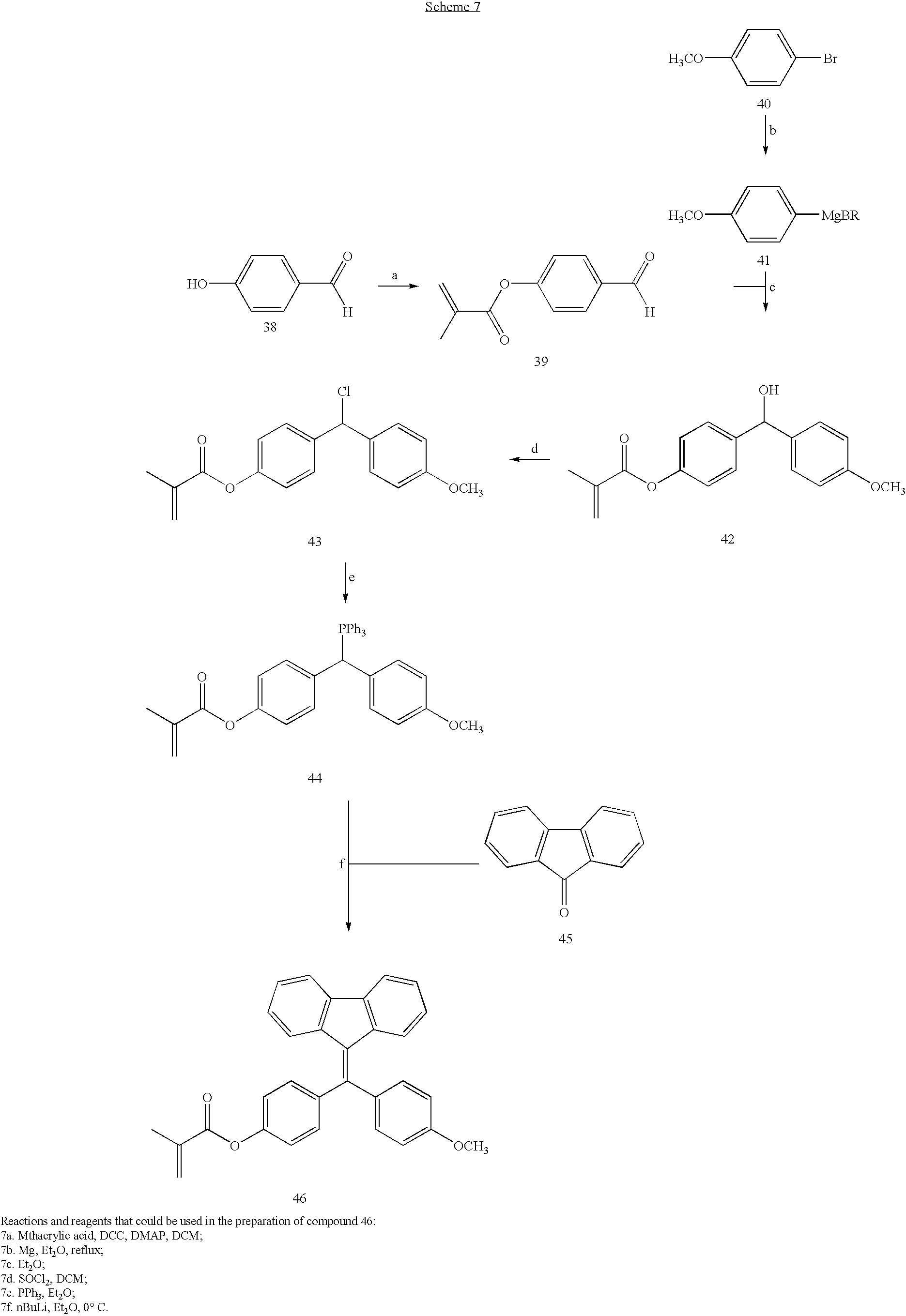

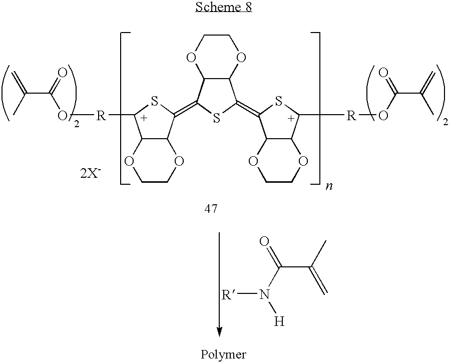

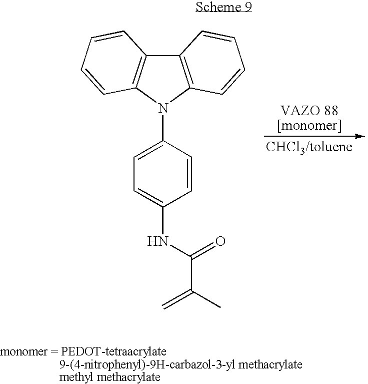

### Standard Polymerization Protocol

A flame dried assembly of a 2-neck round bottom flask fitted with a glass topper, coldfinger condenser, and egg-shaped stir bar is vacuumed and purged with nitrogen repeatedly (four times) to ensure an inert atmosphere before 1.25 mmol of N-(4-(9H-carbazol-9-yl)phenyl)methacrylamide (compound 5) is added to the flask. 5 mL of a 1:1 mixture of chloroform and toluene is injected into the reaction flask to start dissolving the solid. Additional monomers are added at this step for the syntheses of co-polymers. A measured amount (5 mol %) of VAZO 88 is charged into the reaction and the solution brought to reflux. The polymerization reaction is allowed to run for 36-48 hours and then quenched by addition of methanol to yield a 10-fold dilution in methanol. Polymer is obtained in high yield by centrifuging the suspended monomer and decanting the supernate from the pellet. The pellet is then re-dissolved in chloroform or dichloromethane and then re-precipitated with a 10-fold dilution of methanol and re-centrifuged. The supernate is once again discarded and the pellet dried under vacuum.

### Co-polymerization of N-(4-(9H-carbazol-9-yl)phenyl)methacrylamide (CPMAAm) and methylmethacrylate (MMA) [co-pCPMAAM:pMMA]

In a flame dried, and nitrogen purged flask, N-(4-(9H-carbzol-9-yl)phenyl)methacrylamide (0.1630 g, 0.5000 mmol) and methyl methacrylate (0.054 mL, 0.5000 mmol) were dissolved in a 1:1 solution of chloroform and toluene (1 mL:1 mL). The solution was then charged with VAZO88 (0.0061 g, 0.025 mmol) and heated to reflux. After 48 hours, the solution was quenched with methanol and the solids centrifuged out from the supernate. The supernate was discarded and the solids re-dissolved in chloroform, and then precipitated once again in methanol. The solids were centrifuged from the liquid, the liquid removed, and the resulting pellet dried under vacuum.

### Thickness Profiles

X-ray reflectivity (XRR) and ellipsometry were used to determine the thicknesses of polymer 5 on bare SiO₂ surfaces and on PEDOT:PSS films on SiO₂. The thicknesses were measured as a function of both solution concentration and spin coat spin speed. For the XRR measurements, the film thicknesses were determined from fits of the Keissing fringes. XRR fits of a polymer 5 film on SiO₂ and of a polymer 5 film on poly(ethyleneoxythiophene):poly(styrenesulfonate) (PEDOT:PSS) were used to determine the N and K values for each case, respectively. These values were used for the ellipsometric modeling of the films. XRR measurements were made on a Bede Defractometer Scanning Omega-2θ from 300 to 6000 arcsec. Ellipsometric measurements were made using a variable wavelength J. A. Woollam VASE ellispometer.

### Roughness Profiles

Surface roughness was determined from non-contact mode atomic force microscopy images of surface topography of polymer 5 films on PEDOT:PSS films on commercially available ITO coated glass substrates. Images were collected using a Thermomicroscope CP Research AFM in non-contact mode with silicon tips with Al backside coating and an average resonance of 300 kHz (Mikromasch NSC15). The roughness measurements are an average over the entire area of the image.

### Bandgap Profiles

The highest occupied molecular orbital (HOMO) and lowest unoccupied molecular orbital (LUMO) energy levels and the polymer bandgap were determined by UV-Vis and cyclic voltammetry. The HOMO and LUMO levels were determined from voltage of the onset of the anodic and cathodic peaks. The HOMO level was also determined from the onset of UV absorption. Electrochemical measurements were made on films spun directly onto ITO. The ITO was used as the working electrode, a Pt wire as the counter electrode and an Ag/AgCl electrode as the reference electrode and 100 mM TBATFB in acetonitrile was used as the electrolyte. Electrochemical measurements were performed using a BAS Epsilon potentiostat. UV-Vis spectra were collected for the solvated polymer in toluene. It was determined that the HOMO and LUMO were at −2.1 eV and −5.5 eV from the vacuum level, respectively. Spectra were collected using a Hewlett Packard 8452A Diodearray UV-Vis Spectrophotometer.

### Fabrication of an Organic Light-Emitting Diode Based on a Novel Hole-Transport Polymer

A multilayer OLED was fabricated using a combination of solution processing and chemical vapor deposition (CVD). The structure of this stack was indium tin oxide (ITO), PEDOT:PSS (31 nm), Polymer 5 (12 nm), Alq₃ (30 nm), LiF (0.7 nm) and a cathode comprising Al.

ITO-coated glass was cleaned thoroughly by sonication in a 2% Tergitol solution, followed by a rinsing in de-ionized water and immersion for 10 minutes in a 5:1:1 solution of DI water:ammonium hydroxide:hydrogen peroxide heated to 70° C. Substrates were then rinsed with DI water and sonicated in acetone and methanol for 15 minutes each. After drying with nitrogen, they were cleaned with UV/ozone to remove any remaining organic contaminants. Spin-coating of PEDOT:PSS and polymer 5 was performed in a nitrogen-filled glove box. A 1:3 solution (0.3 ml) of Baytron P in methanol was cast onto the ITO substrate. After the solution had completely wet the surface, the substrate was accelerated to 3000 rpm for 1 second, then to 6000 rpm and held at that rate for 30 seconds. The film was annealed on a hotplate inside the glove box at 125° C. for 10 minutes. After annealing, the substrate was placed on the spin-coater, and of a 5 mg/ml solution (0.1 ml) of polymer 5 in toluene/chloroform was dropped onto the surface. The substrate was accelerated to 3000 rpm and held at this rate for 60 seconds. The resultant film was annealed at 120° C. for 20 minutes. The substrate with the PEDOT:PSS/polymer 5 bi-layer was moved in an inert atmosphere to a vacuum chamber. A 30 nm film of Alq₃ was deposited onto the substrate by thermal evaporation at a rate of ˜5 Å s⁻¹. Film deposition was carried out at a base pressure of 2×10⁻⁶ mbar. The chamber was vented and a shadow masked for depositing patterned cathodes was placed over the device. The device was placed back into the chamber and pumped to a base pressure of 2×10⁻⁶ mbar. A bi-layer of lithium fluoride and aluminum was deposited using thermal evaporation at a rate of 0.1 Å s⁻¹ for LiF and 5-25 Å s⁻¹ for Al. Finished devices were removed from the chamber and characterized under an inert atmosphere.

As will be appreciated by one of ordinary skill in the art, the polymers described herein may be used in a variety of devices and configurations. The following chart provides some examples of possible configurations which can be used in a typical OLED stack.

Chart showing various exemplary configurations for devices described here:

| | HIL | Interlayer | HTL | EML | HBL | ETL |
|---|---|---|---|---|---|---|
| 1 | • | • | • | • | • | • |
| 2 | • | | • | • | • | • |
| 3 | • | • | • | • | | • |
| 4 | • | | • | • | | • |
| 5 | • | • | • | • | | |
| 6 | • | | • | • | | |

hole injection layer (HIL): May comprise ITO, a self assembled monolayer formed on the ITO or a polymer layer formed on the ITO such as PEDOT:PSS;
Interlayer: May comprise a material such as a poly aniline;
hole transport layer (HTL): The described polymer;
emissive layer (EML): Can be one of small molecule electroluminescent (EL), small molecule electrophosphorescent (EP), quantum dot (QD), light emitting polymer (LEP) or any combination thereof;
hole blocking layer (HBL): Can be any suitable small molecule such as BCP, TAZ or TPBi or a polymer;
electron transport layer (ETL): Can be a small molecule such as Alq3 or a polymer.

Various compounds may be used for the layers described above, as known in the art.

### REFERENCES

1. (a) H. Vestweber, J. Oberski, A. Grainer, W. Heitz, R. F. Mahrt and H. Bässler, Adv. Mater. Opt. Elect. 2, 197 (1993); (b) M. Deurβen and H. Bässler, Chem. Unserer Zeit 31, 76 (1997).
2. I. D. Parker, J. Appl. Phys. 75, 1656 (1994).
3. C. W. Tang and S. A. Van Slyke, Appl. Phys. Lett. 51, 913 (1987).
4. Y.-H. Tak, H. Vestweber, H. Bässler, A. Bleyer, R. Stockmann and H.-H. Hörold, Chem. Phys. 212, 471 (1996).
5. J. Littmann and P. Martic, J. Appl. Phys. 72, 1957 (1992).
6. N. Tamoto, C. Adachi and K. Nagai, Chem. Mater. 9, 1077 (1997).
7. T. Sano, T. Fujii, Y. Nishio, Y. Hamada, K. Shibata and K. Kuroki, Jpn. J. Appl. Phys. 34 (6A), Part 1, 3124 (1995).
8. S. Saito, T. Tsutsui, M. Era, N. Takada, C. Adachi, Y. Hamada and T. Wakimoto, Proc. SPIE 1910, 212 (1993).
9. C. H. Chen, J. Shi and C. W. Tang, Macromol. Symp. 125, 1 (1997).
10. J. Kido, Jpn. J. Appl. Phys. 31, Part 2, L917 (1993).
11. M. Thelakkat and H.-W. Schmidt, Polym. Adv. Technol. 9, 429 (1998).
12. J. Kalinowski, J. Phys. D: Appl. Phys. 32, R179 (1999).
13. M. S. Weaver and D. D. C. Bradley, Synth. Met. 83, 61 (1996).
14. A. B. Holmes, D. D. C. Bradley, A. R. Brown, P. L. Burn, J. H. Burroughes, R. H. Friend, N. C. Greenham, R. W. Gymer, D. A. Halliday, R. W. Jackson, A. Kraft, J. H. F. Martens, K. Pichler and I. D. W. Samuel, Synth. Met. 57, 4031 (1993).

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

All patents and publications mentioned in the specification are indicative of the levels of skill of those skilled in the art to which the invention pertains. References cited herein are incorporated by reference herein in their entirety to indicate the state of the art, in some cases as of their filing date, and it is intended that this information can be employed herein, if needed, to exclude (for example, to disclaim) specific embodiments that are in the prior art. For example, when a compound is claimed, it should be understood that compounds known in the prior art, including certain compounds disclosed in the references disclosed herein (particularly in referenced patent documents), are not intended to be included in the claim.

When a group of substituents is disclosed herein, it is understood that all individual members of those groups and all subgroups, including any isomers and enantiomers of the group members, and classes of compounds that can be formed using the substituents are disclosed separately. When a compound is claimed, it should be understood that compounds known in the art including the compounds disclosed in the references disclosed herein are not intended to be included. When a Markush group or other grouping is used herein, all individual members of the group and all combinations and subcombinations possible of the group are intended to be individually included in the disclosure.

Every formulation or combination of components described or exemplified can be used to practice the invention, unless otherwise stated. Specific names of compounds are intended to be exemplary, as it is known that one of ordinary skill in the art can name the same compounds differently. When a compound is described herein such that a particular isomer or enantiomer of the compound is not specified, for example, in a formula or in a chemical name, that description is intended to include each isomers and enantiomer of the compound described individual or in any combination. One of ordinary skill in the art will appreciate that methods, device elements, starting materials, dopants, and synthetic methods other than those specifically exemplified can be employed in the practice of the invention without resort to undue experimentation. All art-known functional equivalents, of any such methods, device elements, starting materials, dopants, and synthetic methods are intended to be included in this invention. Whenever a range is given in the specification, for example, a composition range, all intermediate ranges and subranges, as well as all individual values included in the ranges given are intended to be included in the disclosure.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements. The invention illustratively described herein suitably may be practiced in the absence of any element or elements, limitation or limitations which is not specifically disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

In general the terms and phrases used herein have their art-recognized meaning, which can be found by reference to standard texts, journal references and contexts known to those skilled in the art. The following definitions are provided to clarify their specific use in the context of the invention.

One skilled in the art readily appreciates that the present invention is well adapted to carry out the objects and obtain the ends and advantages mentioned, as well as those inherent in the present invention. The methods, components, materials and dimensions described herein as currently representative of preferred embodiments are provided as examples and are not intended as limitations on the scope of the invention. Changes therein and other uses which are encompassed within the spirit of the invention will occur to those skilled in the art, are included within the scope of the claims.

Although the description herein contains certain specific information and examples, these should not be construed as limiting the scope of the invention, but as merely providing illustrations of some of the embodiments of the invention. Thus, additional embodiments are within the scope of the invention and within the scope of the claims.

We claim:

1. A polymer precursor for use in organic electronic devices comprising:
(a) one or more polymerizable compounds comprising
(1) an acryl group; and
(2) one or more groups selected from the following: a triarylamine group, a phenylamine group, a carbazole group, a thiophene group, and a fluorene group; and
(b) optionally one or more additive compounds comprising
(1) a polymerizable or cross-linkable group; and
(2) one or more groups selected from the following: —CN, R—(CH₂)ₙ, R—R, R-alkene-R, and R—[O—(CH₂)₂—]ₙ, where R is an aromatic group and n is an integer from 1 to 10.

2. The polymer precursor of claim 1, wherein a polymerizable compound has the formula:

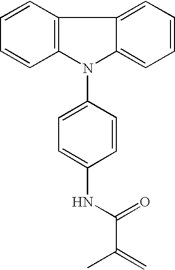

3. The polymer precursor of claim 1 wherein a polymerizable compound has the formula:

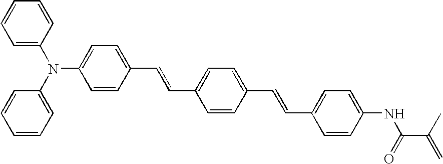

4. The polymer precursor of claim 1 wherein a polymerizable compound has the formula

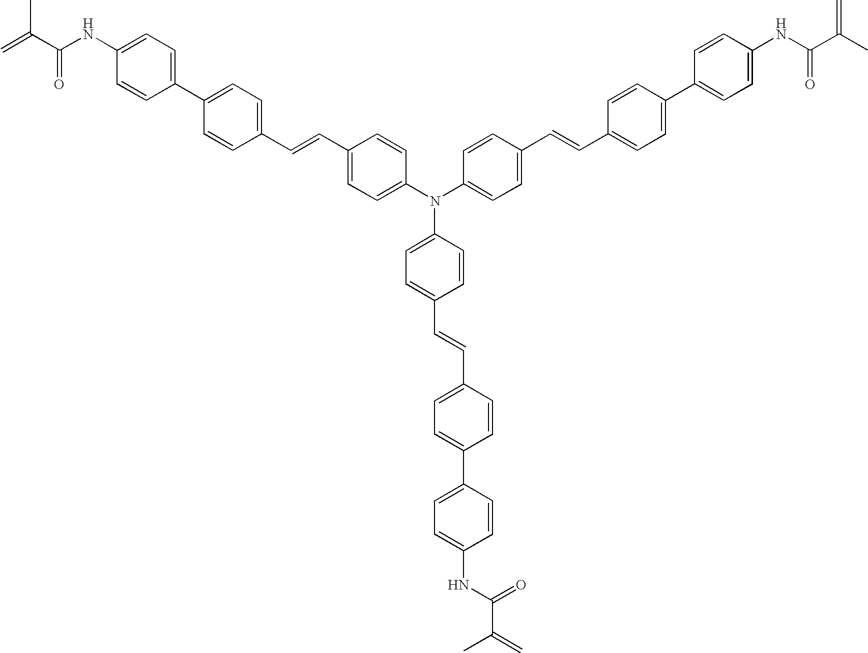

5. The polymer precursor of claim 1 wherein a polymerizable compound comprises an acryl group and a carbazole group linked together with one or more methylene groups.

6. The polymer precursor of claim 5, wherein a polymerizable compound comprises one or more of the following:

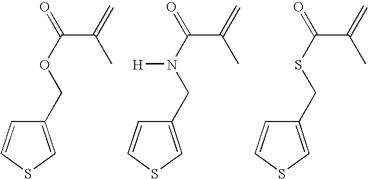

7. The polymer precursor of claim 1, wherein a polymerizable compound further comprises a polymerizable or cross-linkable group which is not an acryl group.

8. The polymer precursor of claim 7, wherein the polymerizable or cross-linkable group is selected from the group consisting of:

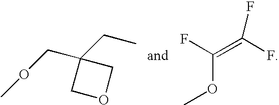

9. The polymer precursor of claim 1, wherein the cross-linkable group is an oxetane or trifluorovinyloxy group.

10. The polymer precursor of claim 1, wherein an additive group comprises an acryl group, a phenyl group and a C₂-C₁₀ alkyl or —[O—(CH₂CH₂)]ₙ group, where n is an integer from 1 to 10.

11. The polymer precursor of claim 1, wherein the organic electronic device is an OLED device.

12. The polymer precursor of claim 1, wherein the organic electronic device is a solar cell.

13. The polymer precursor of claim 1, wherein the organic electronic device is an organic thin film transistor.

14. A hole transport polymer for use in an OLED device comprising the precursor of claim 1 which has been polymerized.

15. An OLED device comprising:
a transparent substrate;
a hole injection layer;
an optional interlayer;
a polymer of claim 14;
an emitting layer;
an optional electron transport layer;
a cathode.

16. An OLED device wherein the emitting layer comprises (a) one or more of: a small molecule electroluminescent molecule, a small molecule electrophosphorescent molecule, a quantum dot, a light emitting polymer; and (b) optionally a hole transport or electron transport molecule or polymer.

17. A method of light emission comprising: applying a voltage to the device of claim 15.

18. A hole transport composition comprising:
an electron deficient compound having one or more polymerizable groups;
one or more optional compounds which adjust the energy levels of the resulting composition or improve the solubility of the polymer in a desired solvent, wherein the composition is polymerized.

19. A method of using a hole transport polymer, comprising spin coating or ink jet printing a film of a hole transport polymer of claim 14 onto a surface which is part of an organic electronic device.
